(19) United States
(12) Patent Application Publication
(10) Pub. No.: US 2005/0087137 A1
(43) Pub. Date: Apr. 28, 2005

(54) Method of fabricating a thin film transistor and manufacturing equipment

(76) Inventors: Yong-In Park, Seoul (KR); Woong-Kwon Kim, Kunpo-shi (KR)

Correspondence Address: MCKENNA LONG & ALDRIDGE LLP, 1900 K STREET, NW, WASHINGTON, DC, 20006, US

(21) Appl. No.: 10/975,386

(22) Filed: Oct. 29, 2004

Related U.S. Application Data
(62) Division of application No. 09/855,694, filed on May 16, 2001, now abandoned.

(30) Foreign Application Priority Data
May 18, 2000 (KR) 2000-26788

(51) Int. Cl. C23C 16/00

(52) U.S. Cl. 118/719

(57) ABSTRACT

A method of forming a thin film transistor includes forming a gate electrode on a substrate, forming an organic layer over the substrate having the gate electrode, curing the organic layer in a first chamber, transferring the substrate having the organic layer from the first chamber to a second chamber without exposing the substrate having the organic layer to oxygen atmosphere during transfer, forming an active layer on the organic layer in the second chamber; and forming source and drain electrodes on the active layer.

This application claims the benefit of Korean Patent Application No. 2000-26788, filed on May 18, 2000, the entirety of which is hereby incorporated by reference.

### BACKGROUND OF THE INVENTION

1. Field of the Invention

The present invention relates to a thin film transistor (TFT), and more particularly, to a TFT having an organic gate-insulating layer.

2. Discussion of the Related Art

A thin film transistor (TFT) is generally used as a switching device. For example, a liquid crystal display (LCD) device widely adopts the TFT for its switching device. Since the TFT is relatively easy to form on large, relatively inexpensive, glass substrates, the TFT is one of the most focused-on devices.

LCDs are based on the optical anisotropy of a liquid crystal (LC). A LC has long, thin molecules whose orientational alignment can be controlled by an applied electric field. When the alignment of the LC molecules is appropriately controlled, an applied light is refracted along the alignment direction of the LC molecules such that an image is displayed.

Active matrix (AM) LCDs, in which thin film transistors (TFTs) and pixel electrodes are arranged in an array matrix, are typically used because of their high resolution and superiority in displaying moving images. In an AM LCD, each TFT serves as a switch for a corresponding pixel. A “switched on” pixel transmits incident light.

In an off state of a TFT, the TFT serves to prevent a cross talk between closely spaced unit pixels and serves to extend a period of a signal applied to a liquid crystal layer.

FIG. 1 is a cross-sectional view illustrating a conventional LCD panel 20. As shown, the LCD panel has lower and upper substrates 2 and 4, and an interposed liquid crystal layer 10. The lower substrate 2 includes a substrate 1, a TFT “S” as a switching element to selectively change the orientation of the liquid crystal molecules, and a pixel electrode 14 for the application of a voltage that produces an electric field across the liquid crystal layer 10 in accordance with signals from the TFT “S”. The upper substrate 4 has a color filter 8 for providing color. A common electrode 12 is formed on the color filter 8. The common electrode 12 together with the pixel electrode produces the electric field across the liquid crystal layer 10. The pixel electrode 14 is arranged over a pixel portion “P”, i.e., a display area. Further, to prevent leakage of the liquid crystal layer 10 between the substrates 2 and 4, the substrates 2 and 4 are sealed by a sealant 6. The nematic, smectic, and cholesteric liquid crystals are most widely used in the above-mentioned LCD panel.

When an electric signal is applied to the gate electrode 26 of the TFT “S”, a data signal can be applied to the pixel electrode 14. Thus, unless the electric signal is applied to the gate electrode, a data signal cannot be applied to the pixel electrode 14

A design specification for the lower substrate usually depends on materials and needed specification for the various elements mentioned above. For example, when fabricating a large (such as SXGA and UXGA) LCD device, the resistance of the gate line material can be a critical factor in determining the quality of the LCD device. Therefore, a highly conductive metal, such as aluminum (Al) or an aluminum alloy, is usually used for the gate lines of large LCD devices.

In practice, an inverted staggered type TFT is widely employed due to its advantages of simplicity and high quality. The inverted staggered type TFT can be classified as either a back-channel-etch type or an etching-stopper type, based on the method of forming a channel. As the back-channel-etch type has a simpler structure, a structure of the back-channel-etch type TFTs is shown.

FIG. 2 is a cross-sectional view illustrating a back-channel-etch type TFT used for a typical LCD device. As shown, a gate electrode 30 is formed on a substrate 1, and a gate-insulating layer 32 is formed to cover the gate electrode 30. An active layer 34 is formed on the gate-insulating layer 32, and an ohmic contact layer 36 is formed on the active layer 34. In addition, source and drain electrodes 38 and 40 are formed on the ohmic contact layer 36. The source and drain electrodes 38 and 40 respectively overlap first and second edge portions of the gate electrode 30.

Aluminum (Al) is widely used for the gate electrode 30 because it has a low resistance that reduces RC delays. However, pure aluminum often produces hillocks that can cause defects. Therefore, an aluminum alloy (or an aluminum layer that is covered by another metal such as a refactory metal, for example) is usually used instead of pure aluminum. The source and drain electrodes 38 and 40 are usually made of chromium (Cr) or molybdenum (Mo).

The gate-insulating layer 32 is usually made of silicon nitride (SiNₓ) or silicon oxide (SiO₂), each of which can be deposited at a relatively low temperature (e.g., below 350° C.) and has a superior insulating property. The active layer 34 is usually an amorphous silicon layer (a-Si:H), which also can be deposited at a relatively low temperature.

To form the ohmic contact layer 36, a dopant ion is doped into a portion of the active layer 34. Specifically, a gas having Group III or Group V atoms such as phosphorous (P) or boron (B) is used for the above-mentioned ion dopant. A typical LCD device usually adopts a phosphorous doped amorphous silicon layer (n⁺ a-Si:H) for the ohmic contact layer 36. When the phosphorous doping is applied, for example, PH₃ doping gas including phosphorous (P) is used.

As explained above, a typical TFT used for an LCD device is formed by depositing not only metal layers including the gate electrode 30 but also silicon layers including the gate-insulating layer 32, active layer 34, and ohmic contact layer 36. The gate-insulating layer 32, active layer 34, and ohmic contact layer 36 are deposited using the same deposition equipment, for example, a plasma enhanced chemical vapor deposition system (PECVD).

In case of the gate-insulating layer 32, after a mixture of gas including NH₃, N₂, and SiH₄ gases is allowed into the PECVD system, the mixture of gas is decomposed under a plasma condition. Then, a silicon nitride (SiNₓ) film is formed from the decomposed mixture gas such that the gate-insulating layer 32 is achieved.

For the active layer 34, after the above-mentioned NH₃ and N₂ gases are discharged from the PECVD system, H₂ gas is additionally introduced. Then, the above-mentioned SiH₄ gas and H₂ gas are used together to form a pure amorphous silicon layer (a-Si:H), the active layer 32. In addition, to form the ohmic contact layer 36, a small quantity of PH₃ doping gas is further added to the mixture of SiH₄ and H₂ gases in the PECVD system. Then, the phosphorous doped amorphous silicon layer (n⁺ a-Si:H) for the ohmic contact layer 36 is formed from the mixture of SiH₄, H₂, and PH₃ gases.

For the above-mentioned thin film transistor “S”, silicon nitride (SiNₓ) is used as the gate-insulating layer 32. However, when the gate-insulating layer 32 is silicon nitride (SiNₓ), a parasitic capacitance “C” is present between the gate electrode 30 and the source electrode 38, and between the gate electrode 30 and the drain electrode 40. Since silicon nitride generally has a dielectric constant of about 6, the above-mentioned parasitic capacitance “C” has some (non-negligible) effect on the display quality of the LCD device.

In addition, for a high resolution LCD device, the gate electrode (gate line) is preferred to be thick or wide such that the gate electrode (gate line) has a lower resistance. Since a wide gate electrode (gate line) causes poor aperture ratio, a thick gate electrode (gate line) is preferred over the wide one. However, a thick gate electrode (gate line) may cause a break in the gate-insulating layer.

To avoid the above-mentioned problem of the thick gate electrode, an organic gate-insulating layer has been recently researched and developed. For a typical organic gate-insulating layer, benzocyclobutene (BCB) used for a passivation layer of a typical LCD device is usually used. Since BCB has a dielectric constant of below 3, it causes a smaller parasitic capacitance than silicon nitride which has a dielectric constant of about 6. In addition, since BCB has a superior flatness, it is suitable for the gate-insulating layer to cover the thick gate electrode.

FIG. 3 is a cross-sectional view illustrating a TFT having a BCB gate-insulating layer 33. As shown, even with a gate electrode 30, the BCB gate-insulating layer 33 provides a flat surface. Because of the flat surface of the BCB gate-insulating layer 33, source and drain electrodes 38 and 40 as well as the active layer 34 on the BCB gate-insulating layer 33 are formed to have proper shapes.

FIG. 4 is a block diagram illustrating a conventional process for forming the above-mentioned BCB gate-insulating layer. At first, BCB is deposited on a substrate having a gate electrode. Since BCB remains liquid under atmospheric conditions, it must be cured after be deposited. Curing of BCB is usually performed under nitrogen gas (N₂) atmosphere in a heated oven. Since nitrogen gas is an inert gas, the above-mentioned nitrogen gas (N₂) atmosphere prevents BCB from combining with oxygen gas (O₂). After curing, an active layer is formed in a vacuum equipment. Then, source and drain electrodes are formed in a later process.

For the above-mentioned conventional process for forming the BCB gate-insulating layer, the substrate having a BCB film is in an atmospheric condition during a transfer from the heat oven to the vacuum equipment, after curing. In that case, atmospheric oxygen gas may combine with the surface of the BCB film, or contaminants in the atmosphere may be attached to the surface thereof such that the BCB film is contaminated. If the, BCB film has a contaminated surface, an interface property between the BCB gate-insulating layer and the active layer is deteriorated. Returning to FIG. 3, an interface “F” between the gate-insulating layer 33 and active layer 34 directly affects an on-current property of the TFT “S”. As mentioned above, if the interface “F” is poor, the electric characteristices of the TFT “S” deteriorats. Returning to FIG. 4 illustrating the conventional process, the BCB film is present in the atmosphere during a transfer between the curing of the BCB film and the forming of the active layer. Then, the surface of the BCB film is contaminated such that the BCB gate-insulating layer made of the BCB film and the active layer which will be formed later have a poor interface property therebetween.

### SUMMARY OF THE INVENTION

Accordingly, the present invention is directed to a method of fabricating a thin film transistor and manufacturing equipment that substantially obviates one or more of the problems due to limitations and disadvantages of the related art.

An object of the present invention is to provide a method of fabricating a thin film transistor including an organic gate-insulating layer having an improved interface property.

Additional features and advantages of the invention will be set forth in the description which follows, and in part will be apparent from the description or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, A method of fabricating a thin film transistor, the method comprising forming a gate electrode of the thin film transistor on a substrate; depositing an organic insulating layer over the substrate having the gate electrode; transferring the substrate to a heating and deposition equipment; heating the substrate in the equipment under vacuum and curing the organic insulating layer; and forming a silicon layer on the organic insulating layer in the equipment without breaking the vacuum.

In another aspect of the prensent invention, an apparatus for fabricating a thin film transistor, wherein the thin film transistor includes an organic insulating layer and an active layer having a first amorphous silicon layer and a doped amorphous silicon layer over a substrate, the apparatus comprising a first reaction chamber for curing the organic insulating layer; a second reaction chamber for forming the first amorphous silicon layer; a third reaction chamber for forming the doped amorphous silicon layer; and a preparation chamber for providing a vacuum condition, wherein the preparation chamber is adjacent the first, second and third reaction chambers and the substrate is transferred from the first chamber to the second chamber under the vacuum condition through the preparation chamber.

In another aspect of the present invention, an apparatus for fabricating a transistor, wherein the transistor includes an organic layer and a semiconductor layer, the apparatus comprising a first chamber for curing the organic layer; a second chamber for forming the semiconductor layer; and a preparation chamber adjacent the first and second chambers, wherein the preparation chamber allows a product being formed into the transistor to transfer between the first and second chambers under vacuum.

In another aspect of the present invention, A method of making a liquid crystal display device having a first substrate and a second substrate, the method comprising forming a gate electrode on the first substrate; forming an organic layer over the first substrate having the gate electrode; curing the organic layer in a first chamber; transferring the first substrate having the organic layer from the first chamber to a second chamber without exposing the first substrate having the organic layer to oxygen atmosphere during transfer; forming an active layer on the organic layer in the second chamber; forming source and drain electrodes on the active layer; forming a pixel electrode connected to the drain electrode; and forming a liquid crystal layer between the first substrate and the second substrate.

It is to be understood that both the foregoing general description and the following detailed description are exemplary and explanatory and are intended to provide a further explanation of the invention as claimed.

### BRIEF DESCRIPTION OF THE DRAWING

The accompanying drawings, which are included to provide a further understanding of the invention and are incorporated in and constitute a part of this specification, illustrate an embodiment of the invention and together with the description serve to explain the principles of the invention.

In the drawings:

FIG. 1 is a cross-sectional view illustrating a liquid crystal display device according to the related art;

FIG. 2 is a cross-sectional view illustrating a typical back-channel-etch type TFT used for an LCD device;

FIG. 3 is a cross-sectional view illustrating a TFT having a typical BCB gate-insulating layer;

FIG. 4 is a block diagram illustrating a conventional process for forming the BCB gate-insulating layer of the TFT shown in FIG. 3;

FIG. 5 is a plan view illustrating a vacuum equipment according to the preferred embodiment of the present invention; and

FIG. 6 is a block diagram illustrating a process for forming a BCB gate-insulating layer according to the preferred embodiment.

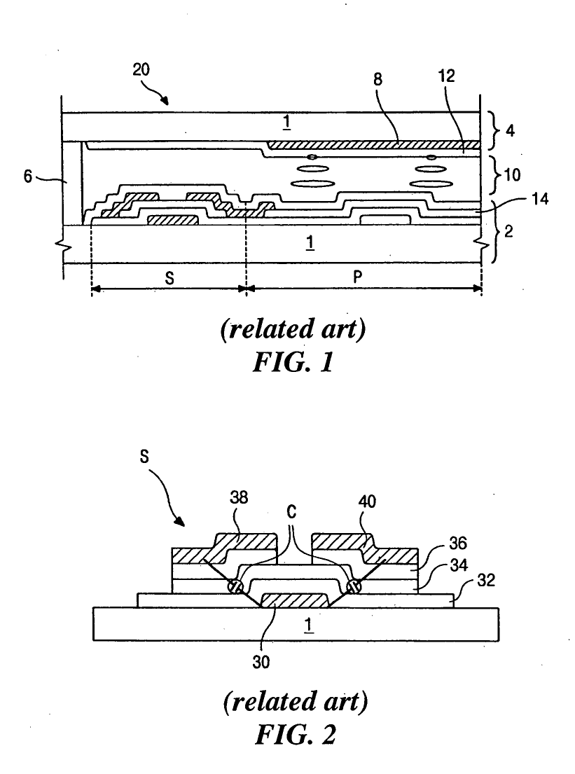

### DETAILED DESCRIPTION OF THE ILLUSTRATED EMBODIMENTS

Reference will now be made in detail to the illustrated embodiments of the present invention, an example of which is shown in the accompanying drawings.

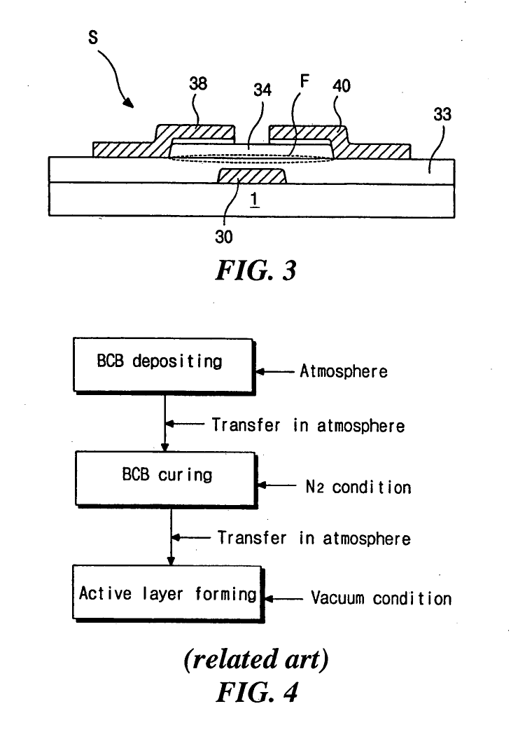

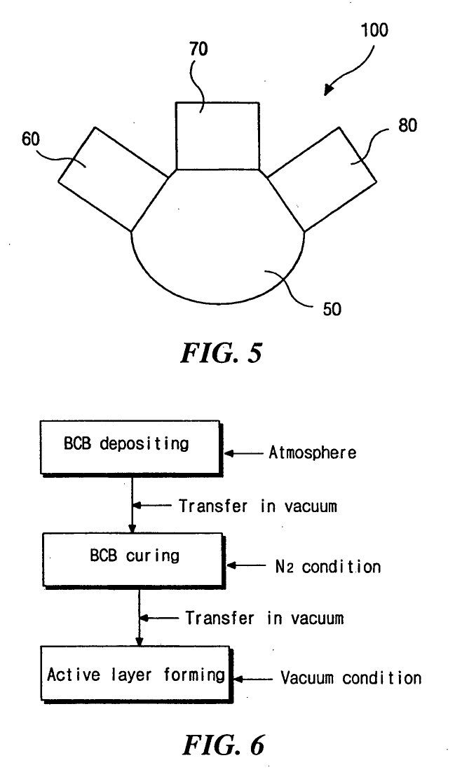

FIG. 5 illustrates a vacuum equipment 100, which is used for fabricating a BCB gate-insulating layer (reference 33 of FIG. 3) of a thin film transistor (reference “S” of FIG. 3), according to the preferred embodiment of the present invention. The inventive vacuum equipment 100 has a preparation chamber 50, which is unified with first to third reaction chambers 60, 70, and 80. The first reaction chamber 60 is used for curing the BCB gate-insulating layer, whereas the second and third reaction chambers 70 and 80 are used for forming an active layer. Each of the first to third reaction chambers 60 to 80 preferably has a heat plate (not shown) that controls a temperature of the reaction chamber. Each heat plate (not shown) of the first to third reaction chambers 60 to 80 serves to control a temperature of elements or layers fabricated in the corresponding reaction chamber.

When the elements are formed and sequentially moved from the first to third reaction chambers 60 to 80, a vacuum condition is maintained in the preparation chamber 50 of the vacuum equipment 100. Thus, the thin film transistor is always shielded from outside atmosphere during the fabricating process thereof.

FIG. 6 is a block diagram illustrating a fabricating process for the thin film transistor having the BCB gate-insulating layer according to the present invention. At first, an organic insulating layer, such as a BCB film, for the gate-insulating layer is deposited on a substrate (reference 1 of FIG. 3) having a gate electrode (reference 30 of FIG. 3). A spin coating or other suitable process is preferably used to deposit the BCB film on the substrate. Then, the substrate on which the BCB film is deposited, is transferred to the preparation chamber 50 of the vacuum equipment 100. While vacuum is maintained in the preparation chamber 50, the substrate is moved into the first reaction chamber 60. In the first reaction chamber 60, the BCB film deposited on the substrate is cured at about 250° C. under an inert gas condition. Nitrogen gas (N₂) is preferably used as the inert gas.

After the curing of the BCB film is finished, the substrate is moved from the first reaction chamber 60 to the second reaction chamber 70, and then to the third reaction chamber 80 without breaking the vacuum. In the second and third reaction chamber 70 and 80, an active layer including a first (such as pure) silicon layer (not shown) and a second (such as doped) silicon layer (not shown) may be formed, respectively. After the above-mentioned first silicon layer and second silicon layer are formed, other elements such as source and drain electrodes (reference 38 and 40 of FIG. 3) are formed using known suitable fabricating processes thereof.

Instead of BCB other organic materials may be used for the gate insulating layer including acryl. A gate-insulating layer made of acryl film can be used as a gate-insulating layer covering the gate electrode on the substrate. The above-explained forming process is also suitable for the acryl gate-insulating layer.

As explained above, the curing of the organic film such as BCB film and the forming of an active layer are performed under vacuum. Since the organic film is shielded from outside atmosphere during the curing, the interface between the organic film and the active layer improves.

In addition, to fabricate the thin film transistor having the organic gate-insulating layer such as BCB, the present invention preferably uses a vacuum equipment 100 where the first to third reaction chambers 60 to 80 and the preparation chamber 50 are an integrated unit or combined as one unit. The preparation chamber 50 serves to provide a vacuum condition such that the substrate having various elements of the thin film transistor on fabrication are transferred in and out of the reaction chambers under the vacuum condition. The first reaction chamber 60 preferably serves as a heating oven to cure the organic film, and the second and third reaction chambers 70 and 80 preferably serve to deposit the first silicon layer and the second silicon layer, respectively. Thus, a heating oven and a silicon deposition apparatus are unified together in the vacuum equipment 100. The first reaction chamber 60 serves as the heating oven, whereas the second and third reaction chambers 70 and 80 serve as the silicon deposition apparatus.

It will be apparent to those skilled in the art that various modifications and variation can be made in the illustrated device and method without departing from the spirit or scope of the invention. Thus, it is intended that the present invention covers the modifications and variations of this invention that come within the scope of the appended claims and their equivalents.

1-5. (canceled)

6. An apparatus for fabricating a thin film transistor, wherein the thin film transistor includes an organic insulating layer and an active layer having a first amorphous silicon layer and a doped amorphous silicon layer over a substrate, the apparatus comprising:
a first reaction chamber for curing the organic insulating layer;
a second reaction chamber for forming the first amorphous silicon layer;
a third reaction chamber for forming the doped amorphous silicon layer; and
a preparation chamber for providing a vacuum condition,
wherein the preparation chamber is adjacent the first, second and third reaction chambers and the substrate is transferred from the first chamber to the second chamber under the vacuum condition through the preparation chamber.

7. The apparatus of claim 6, wherein the first reaction chamber is capable of introducing inert gas for curing.

8. The apparatus of claim 7, wherein the inert gas includes nitrogen gas (N₂)

9. An apparatus for fabricating a transistor, wherein the transistor includes an organic layer and a semiconductor layer, the apparatus comprising:
a first chamber for curing the organic layer;
a second chamber for forming the semiconductor layer; and
a preparation chamber adjacent the first and second chambers,
wherein the preparation chamber allows a product being formed into the transistor to transfer between the first and second chambers under vacuum.

10. The apparatus for fabricating a transistor according to claim 9, wherein the first chamber heats and cures the organic layer and the second chamber forms the semiconductor layer including amorphous silicon.

11. The apparatus for fabricating a transistor according to claim 9, wherein the first, second and preparation chambers are all in one unit.

12. The apparatus for fabricating a transistor according to claim 9, further comprising a third chamber for forming a second semiconductor layer, the preparation chamber allowing the product being formed into the transistor transfer from the second chamber to the third chamber under vacuum.

13. The apparatus for fabricating a transistor according to claim 9, wherein the first, second, third and preparation chambers are all in one unit.

14. The apparatus for fabricating a transistor according to claim 9, wherein the first chamber is capable of introducing inert gas during curing of the organic layer.

15-20. (canceled)
